(19) United States
(12) Patent Application Publication
(10) Pub. No.: US 2015/0136465 A1
(43) Pub. Date: May 21, 2015

(54) METAL OXIDE VARISTOR DESIGN AND ASSEMBLY

(71) Applicants: Bruce Barton, Huntington, NY (US); Russell Barton, Northport, NY (US)

(72) Inventors: Bruce Barton, Huntington, NY (US); Russell Barton, Northport, NY (US)

(21) Appl. No.: 14/493,035

(22) Filed: Sep. 22, 2014

Related U.S. Application Data
(63) Continuation-in-part of application No. 13/994,069, filed on Jun. 14, 2013, now abandoned.

(30) Foreign Application Priority Data
Dec. 14, 2010 (US) 12968063

(51) Int. Cl. H01C 7/12; H05K 1/16

(52) U.S. Cl. CPC H01C 7/12; H05K 1/16; H05K 2201/10886; H05K 2201/10196
USPC 174/260; 338/21

(57) ABSTRACT

A stacked arrangement of metal oxide varistors includes a plurality of metal oxide varistors with each metal oxide varistor of the plurality of metal oxide varistors having a first lead on a first surface and a second lead on a second surface, the first surface and the second surface being opposite facing surfaces of each metal oxide varistor. The first lead and the second lead of adjacent metal oxide varistors, when placed in a stacked arrangement, are arranged, preferably asymmetrically, and having the same voltages so as not to interfere with one another, thereby result in a more compact stacking of metal oxide varistors, as compared to arrangements known to the state of the art. The stacked arrangement of metal oxide varistor can be mounted on printed circuit boards, in addition to a variety of other uses.

### CROSS-REFERENCE TO PRIOR APPLICATIONS

This is a continuation-in-part of U.S. patent application Ser. No. 13/994,069, filed Jun. 14, 2013, which represents the U.S. National Phase patent application of P.C.T. Application No. PCT/US2011/065001, filed Dec. 14, 2011, and claiming priority from U.S. patent application Ser. No. 12/968,063, filed Dec. 14, 2010, now abandoned.

### BACKGROUND OF THE INVENTION

1. Technical Field of the Invention

The present invention relates, generally, to metal oxide varistor assembly and an improved method for the manufacture of metal oxide varistors for use in surge suppression or surge protection, which provide increased part density, as compared to conventional methods for manufacturing metal oxide varistors currently known to the state of the art.

More particularly, the present invention relates to the assembly of metal oxide varistors for which leads are attached to the metal oxide varistors in an offset manner for allowing adjacent metal oxide varistors to be placed in a side-by-side manner without the lead of one metal oxide varistor interfering with the lead of another, adjacent metal oxide varistor. Such non-interfering leads are preferably to be at the same voltage so that by using, for example, two leads that are set at the same voltage, such leads would not mechanically interfere with one another, thereby making possible a metal varistor stack that can be formed having a near zero, or zero, failure rate.

3. Description of the Prior Art

At present, metal oxide varistors (“MOVs”) are placed side-by-side with spacing for legs and an insulating coating between them. It is also known to the state of the art how to manufacture MOVs into modules with two or more layers and sharing a common lead.

During normal assembly of a surge suppression or surge protection device, the MOVs are placed side-by-side with sufficiently wide enough spacing for the leads and epoxy covering. This limits the number of metal oxide varistors that are able to be placed inside the individual units and, consequently, reduces efficiency.

Luo, U.S. Pat. No. 7,623,019, issued Nov. 24, 2009, discloses a varistor having three parallel ceramic layers with each of the parallel ceramic layers having two electrodes or leads on each of the two sides thereof. The leads of the varistor taught by Luo are not offset from one another, but are illustrated in the drawing figures thereof as being substantially parallel, or adjacent, to one another, as well as also being taught as capable of being set at different voltages from one another, thereby potentially interfering with each other in their placements and unnecessarily increasing the spacing between the parallel ceramic layers.

Ho, U.S. Pat. No. 7,741,946, issued Jun. 22, 2010, discloses a metal oxide varistor having heat protection, however, as the case with the apparatus disclosed by Luo, Ho describes leads that are either at, or could be, at different voltages, thereby resulting in a mechanical interference between the leads, in contrast to the present invention whereby the leads that are to be non-interfering are to be maintained at the same voltage.

### SUMMARY OF THE INVENTION

It is therefore, an object of the present invention to an assembly of metal oxide varistors in which the leads of the adjacent metal oxide varistors are offset from one another thereby avoiding the leads of one metal oxide varistor from interfering with the leads of an adjacent metal oxide varistor.

It is a further object of the present invention to provide an assembly of metal oxide varistors in which the leads of adjacent metal oxide varistors are offset from one another for permitting less spacing, or closer packing, of a plurality of adjacent metal oxide varistors.

It is an additional object of the present invention to provide an assembly of metal oxide varistors in which the leads of adjacent metal oxide varistors are offset from one another so as to avoid the drawbacks inherent in prior art metal oxide varistor assemblies and to allow for greater efficiency at a competitive cost.

The foregoing and related objects are achieved by the present invention for an assembly of a plurality of adjacent metal oxide varistors (“MOVs”) with each of the MOVs of the assembly having leads which are non-interfering with the leads of adjacent MOVs in assembly and with the leads that are intended to be non-interfering with one another being provided with the same voltage. A non-interfering, interlocking or offset, arrangement of adjacent MOV's in an assembly having a plurality of MOVs allows for the inclusion of a greater number of metal oxide varistors in a smaller, or more compact, space, while reducing the costs inherently incurred in seeking to join a plurality of MOVs in a conventional manner where adjacent leads necessarily touch or interfere with one another.

Furthermore, by providing either an offset or interlocking arrangement of leads of adjacent MOVs, the plurality of metal oxide varistors of an assembly of MOVs does not require that the metal oxide varistors be epoxy-coated, as is conventionally the required when electrically connected surfaces touch one another or otherwise interfere with each other.

Other objects and features of the present invention will become apparent when considered in combination with the accompanying drawing figures which illustrate certain preferred embodiments of the present invention. It should, however, be noted that the accompanying drawing figures are intended to illustrate only certain embodiments of the claimed invention and are not intended as a means for defining the limits and scope of the invention.

### BRIEF DESCRIPTION OF THE DRAWING FIGURES

In the drawing, wherein similar reference letters and numerals and symbols denote similar features throughout the several views:

FIG. 1 is a perspective view of three metal oxide varistors having leads, assembled in accordance with the prior art;

FIGS. 2A and 2B are perspective views of three metal oxide varistors sharing common leads, as taught by the prior art of Luo, U.S. Pat. No. 7,623,019;

FIG. 3 is a plan view of two metal oxide varistors having offsetting leads in accordance with the present invention;

FIG. 4 is a side perspective view of two metal oxide varistors arranged adjacent to one another without the leads of a first metal oxide varistor interfering with the leads of a second metal oxide varistor;

FIG. 5 is a bottom perspective view of the two metal oxide varistors of FIG. 4 with their offsetting leads;

FIG. 6 is a side perspective view of four metal oxide varistors arranged adjacent to one another without the leads of a given metal oxide varistor interfering with the leads of one or more adjacent metal oxide varistors;

FIG. 7 is a bottom perspective view of the four metal oxide varistors of FIG. 6 with their offsetting leads;

FIG. 8 is a plan view illustrating a preferred embodiment of two metal oxide varistors having offsetting leads in accordance with the present invention;

FIG. 9 is a side perspective view of two metal oxide varistors having offsetting leads in accordance with the preferred embodiment of FIG. 8 in accordance with the present invention; and,

FIG. 10 is a bottom perspective view of the two metal oxide varistors having offsetting leads of the preferred embodiment of FIG. 8 in accordance with the present invention.

### DETAILED DESCRIPTION OF THE DRAWING FIGURES AND PREFERRED EMBODIMENTS

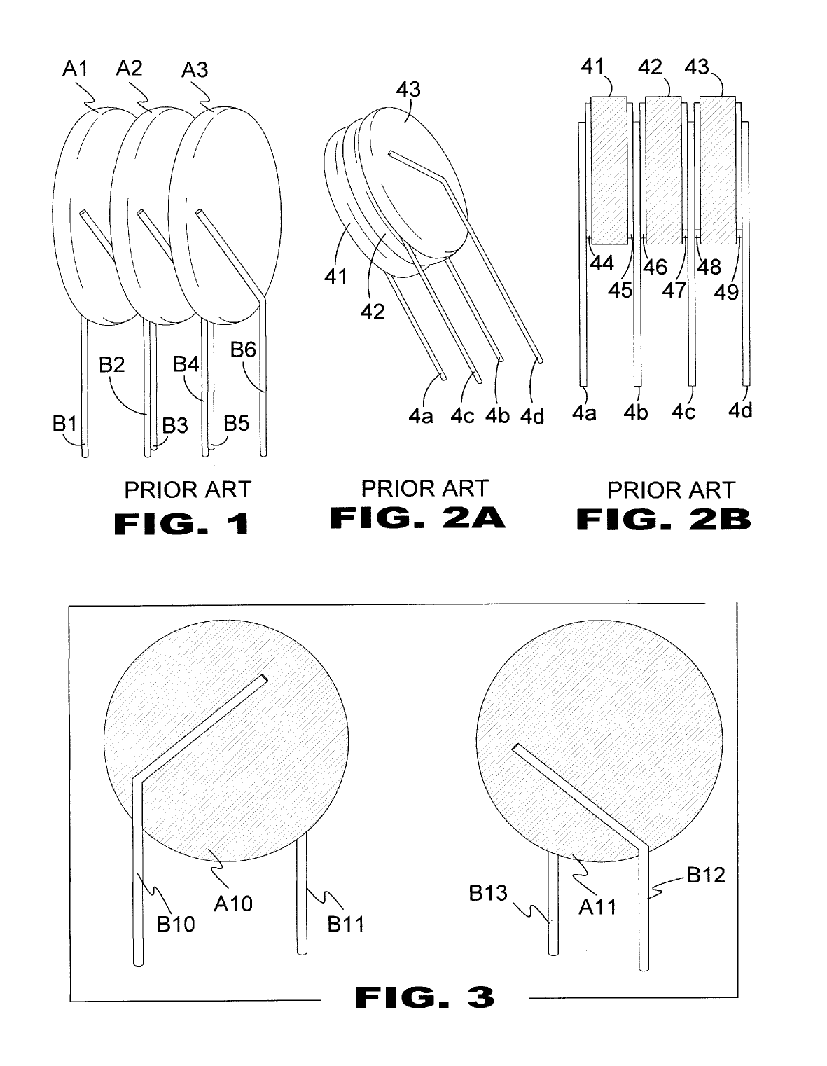

Turning now, in detail, to the accompanying drawing figures, FIG. 1 is a perspective view of three metal oxide varistors (A₁, A₂, A₃) having leads (B₁, B₂, B₃, B₄, B₅, B₆), assembled in accordance with the prior art, in which the leads are not offset relative to one another and therefore touch, or otherwise interfere with, adjacent leads.

FIGS. 2A and 2B are perspective views of three metal oxide varistors sharing common leads, as taught by the prior art of Luo, U.S. Pat. No. 7,623,019, in which three metal oxide varistors (41, 42, 43) sharing two common leads (4b, 4c) for sides of the MOVs which are adjacent other metal oxide varistors, while two leads (4a, 4d) are on outer surfaces and therefore share these leads with no adjacent MOV. In FIG. 2B, electrodes are designated by reference numerals 44, 45, 46, 47. As taught by Luo, the leads can be of, or set at, different voltages thereby resulting in unwanted mechanical interference.

FIG. 3 is a plan view of two metal oxide varistors (A₁₀, A₁₁) having offsetting leads (B₁₀, B₁₁; B₁₂, B₁₃) in accordance with the present invention. Metal oxide varistor (A₁₀) shows a front left, wide lead pattern, while MOV (A₁₁) presents a front right, narrow lead pattern. Further illustrated in FIG. 3 is that the first MOV (A₁₀) has leads (B₁₀, B₁₁) crossing about center and the second MOV (A₁₁) has leads (B₁₂, B₁₃) crossing below center. The arrangement of the leads as being wide and above center, and narrow and below center, allows the metal oxide varistors arranged according to the present invention to be spaced as closely together as illustrated in the prior art assembly of FIG. 2, yet with less expense and without the requirement of having shared leads where MOVs have adjacent surfaces.

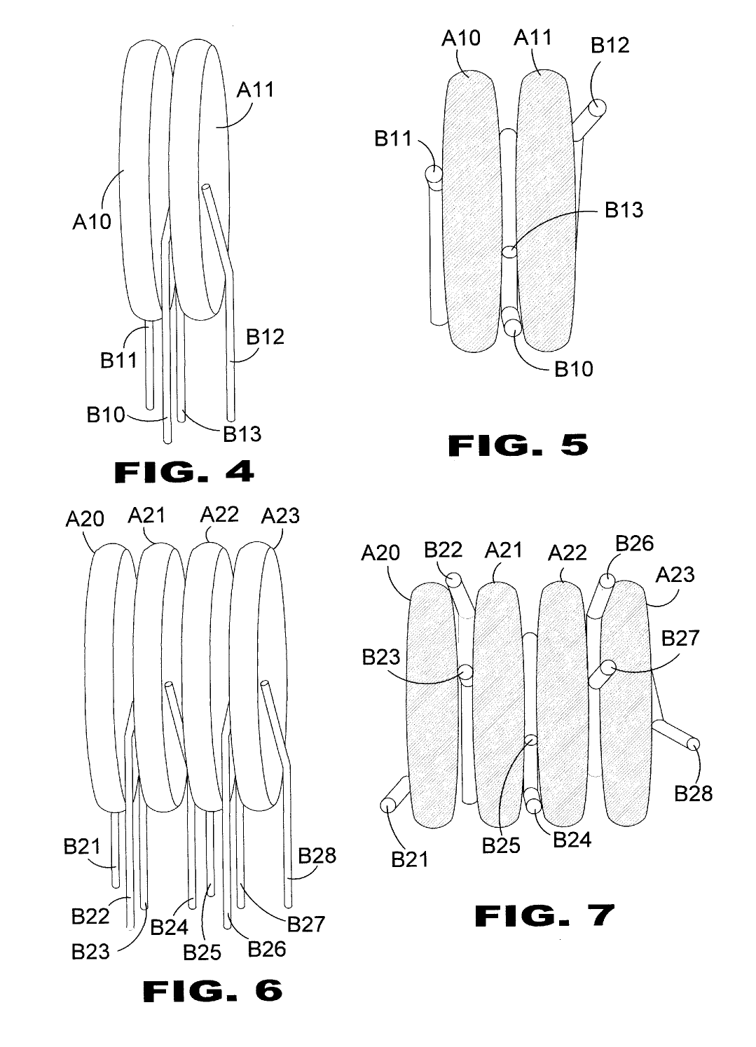

FIGS. 4 and 5 illustrate side and bottom views, respectively, of the two metal oxide varistors (A₁₀, A₁₁), as shown in FIG. 3, arranged tightly adjacent one another without the adjacent leads (B₁₀, B₁₃) interfering with one another. Such an arrangement as that shown in FIGS. 4 and 5 would be feasible and appropriate when installed as part of a printed circuit board and, because the adjacent leads (B₁₀, B₁₃) can be connected together on the printed circuit board, the metal oxide varistors do not need to be epoxy-coated.

FIGS. 6 and 7 illustrate side and bottom views, respectively, of four metal oxide varistors (A₂₀, A₂₁, A₂₂, A₂₃) arranged tightly adjacent one another without the adjacent leads (B₂₂, B₂₃, B₂₄, B₂₅, B₂₆, B₂₇) interfering with one another. The outer leads are designated by reference numerals B₂₁, B₂₈ of the outer metal oxide varistors (A₂₀, A₂₃).

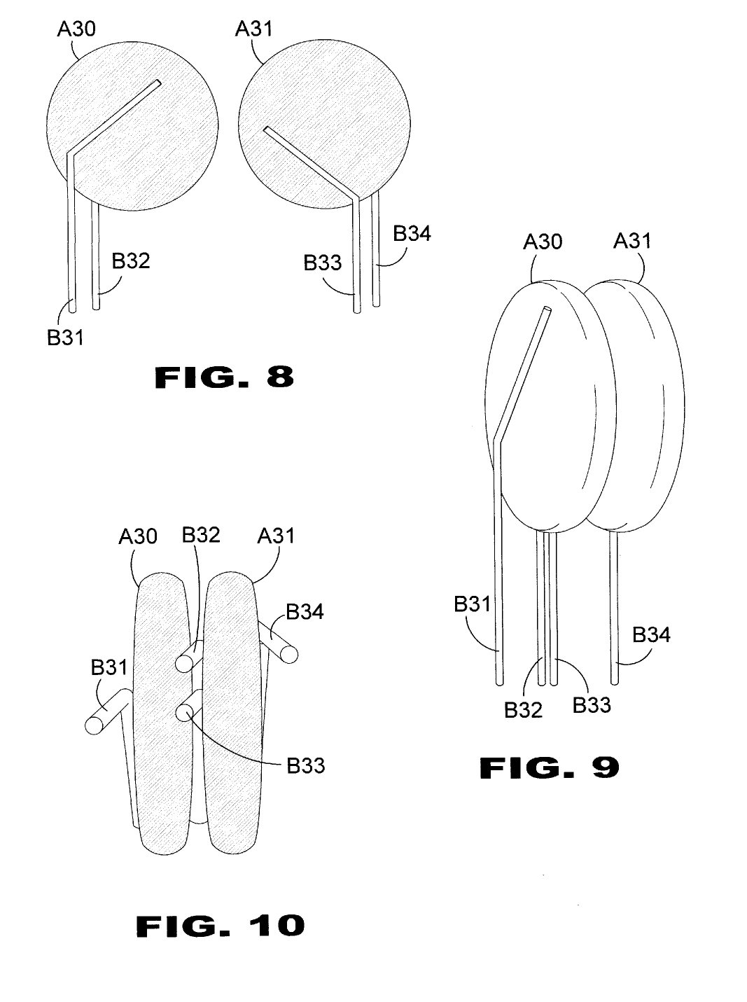

FIG. 8 presents two metal oxide varistors (A₃₀, A₃₁) with metal oxide varistor (A₃₀) showing a left attached lead (B₃₁) having a wide and above center orientation, while MOV (A₃₁) illustrates a right attached lead (B₃₄) having a narrow and below center orientation. The arrangement of the leads (B₃₁, B₃₂, B₃₃, B₃₄), being wide and above center on one side of an MOV shown in FIG. 8, and narrow and below center on the other side of a given MOV, allows the plurality of assembled metal oxide varistors to be spaced closely and without any requirement for having shared leads between adjacently situated MOVs.

FIGS. 9 and 10 present side and bottom views, respectively, of the two metal oxide varistors (A₃₀, A₃₁) arranged tightly together without adjacent leads (B₃₂, B₃₃) interfering with one another due to the arrangement of one of the adjacent leads having a wide and above center orientation, while another adjacent lead has a narrow and below center orientation.

It will be appreciated that any number of metal oxide varistors can be adjacently assembled pursuant to the arrangement of adjacent leads of adjacent MOVs described in accordance with the present invention and that the discussion and illustration of two or four metal oxide varistors is merely exemplary of the scope of the invention.

When a plurality of metal oxide varistors are arranged or stacked in accordance with the present invention, the plurality of stacked MOVs may be mounted to printed circuit boards or to wire or metal busses.

The stacked plurality of metal oxide varistors can also be fully or partially enclosed or enveloped in a ceramic or concrete casing, or optionally encased in epoxy.

While only several embodiments of the present invention have been shown and described, it will be obvious to those skilled in the art that many modifications may be made to the present invention without departing from the spirit and scope thereof.

What is claimed is:

1. A stacked arrangement of metal oxide varistors, comprising:
a first metal oxide varistor having a first lead on a first surface and a second lead on a second surface, said first surface and said second surface being opposite facing surfaces of said first metal oxide varistor; and,
a second metal oxide varistor having a first lead on a first surface and a second lead on a second surface, said first surface and said second surface being opposite facing surfaces of said second metal oxide varistor, said second lead of said first metal oxide varistor and said first lead of said second metal oxide varistor being adjacent one another when placed in a stacked arrangement without said second lead of said first metal oxide varistor and said first lead of said second metal oxide varistor interfering with one another due to said second lead of said first metal oxide varistor and said first lead of said second metal oxide varistor having equal voltages.

2. The stacked arrangement of metal oxide varistors according to claim 1, wherein said second lead of said first metal oxide varistor and said first lead of said second metal oxide varistor are mounted asymmetrically, thereby allowing for tight grouping within said stacked arrangement of metal oxide varistors without said second lead of said first metal oxide varistor and said first lead of said second metal oxide varistor interfering with one another.

3. The stacked arrangement of metal oxide varistors according to claim 2, wherein said second lead of said first metal oxide varistor is mounted wide and above center and said first lead of said second metal oxide varistor is mounted narrow and below center to avoid interfering with one another.

4. A stacked arrangement of metal oxide varistors, comprising:
a plurality of metal oxide varistors with each metal oxide varistor of said plurality of metal oxide varistors having a first lead on a first surface and a second lead on a second surface, said first surface and said second surface being opposite facing surfaces of each metal oxide varistor, with said first lead and said second lead of adjacent said metal oxide varistors of said plurality of metal oxide varistors, when placed in a stacked arrangement, not interfering with one another due to said first lead and said second lead of adjacent said metal oxide varistors having equal voltages.

5. The stacked arrangement of metal oxide varistors according to claim 4, wherein said first lead and said second lead of adjacent said metal oxide varistors of said plurality of metal oxide varistors are mounted asymmetrically.

6. The stacked arrangement of metal oxide varistors according to claim 5, wherein said first lead of adjacent said metal oxide varistors is mounted wide and above center and said second lead of adjacent said metal oxide varistors is mounted narrow and below center.

7. The stacked arrangement of metal oxide varistors according to claim 4, wherein said plurality of metal oxide varistors are, at least partially, enclosed in cement.

8. The stacked arrangement of metal oxide varistors according to claim 4, wherein said plurality of metal oxide varistors are, at least partially, enclosed in epoxy.

9. The stacked arrangement of metal oxide varistors according to claim 4, wherein said plurality of metal oxide varistors are, at least partially, enclosed in ceramic.

10. A printed circuit mount, comprising:
a stacked arrangement of metal oxide varistors having a plurality of metal oxide varistors with each metal oxide varistor of said plurality of metal oxide varistors having a first lead on a first surface and a second lead on a second surface, said first surface and said second surface being opposite facing surfaces of each metal oxide varistor, with said first lead and said second lead of adjacent said metal oxide varistors of said plurality of metal oxide varistors, when placed in a stacked arrangement, not interfering with one another due to said first lead and said second lead of adjacent said metal oxide varistors having equal voltages.

11. The printed circuit board according to claim 10, wherein said first lead and said second lead of adjacent said metal oxide varistors of said plurality of metal oxide varistors are mounted asymmetrically.

12. The printed circuit board according to claim 11, wherein said first lead of adjacent said metal oxide varistors is mounted wide and above center and said second lead of adjacent said metal oxide varistors is mounted narrow and below center.
